(19) United States
(12) Patent Application Publication
(10) Pub. No.: US 2015/0170963 A1
(43) Pub. Date: Jun. 18, 2015

(54) SEMICONDUCTOR DEVICE MANUFACTURING METHOD

(71) Applicant: Tokyo Electron Limited, Tokyo (JP)

(72) Inventors: Tadahiro ISHIZAKA, Yamanashi (JP); Kotaro MIYATANI, Yamanashi (JP); Takuya KUROTORI, Yamanashi (JP)

(21) Appl. No.: 14/564,569

(22) Filed: Dec. 9, 2014

(30) Foreign Application Priority Data
Dec. 13, 2013 (JP) 2013-258193

(51) Int. Cl. H01L 21/768

(52) U.S. Cl. CPC H01L 21/76879; H01L 21/76843; H01L 21/76826

(57) ABSTRACT

A semiconductor device manufacturing method includes: performing nitrogen plasma processing on an interlayer insulating film made of a fluorine containing carbon film having a recess formed in a surface thereof in a predetermined pattern; forming a Ru film directly on the fluorine containing carbon film subjected to the nitrogen plasma processing. The semiconductor device manufacturing method further includes filling a Cu film in the recess to form a Cu wiring.

### CROSS-REFERENCE TO RELATED APPLICATION

This application claims priority to Japanese Patent Application No. 2013-258193 filed on Dec. 13, 2013, the entire contents of which are incorporated herein by reference.

### FIELD OF THE INVENTION

The present invention relates to a method for manufacturing a semiconductor device by forming Cu wiring in a recess such as a trench or a hole formed in a Low-k film on a substrate.

### BACKGROUND OF THE INVENTION

In a semiconductor device manufacturing process, a desired device is manufactured by repetitively performing various processes such as film formation, etching and the like on a semiconductor wafer. Recently, in order to meet demands for miniaturization, high integration and high speed of a semiconductor device, wiring is miniaturized and a wiring width and a gap between wirings become smaller. However, a RC (Resistance-Capacitance) delay caused by increase in wiring resistance and coupling capacitance between wirings deteriorates high-speed operation of a device.

In order to reduce the RC delay of the semiconductor device, it is required to reduce the wiring resistance and the coupling capacitance between the wirings. Further, the reduction in the wiring resistance and the coupling capacitance between the wirings leads to energy saving. Therefore, Cu having a lower resistivity than aluminum (Al) or tungsten (W) which has been conventionally used is used as a wiring material, and a Low-k film having a dielectric constant of 3.0 or less is used as an insulating material between the wirings. As for the Low-k film, a porous SiCOH-based material having a further lower dielectric constant is used.

As for a method for forming Cu wiring, there is proposed a method including: forming a barrier film with tantalum metal (Ta), titanium (Ti), tantalum nitride (TaN), titanium nitride (TiN) or the like on an entire interlayer insulating film having a trench or a hole by plasma sputtering as an example of PVD (Physical Vapor Deposition); forming a Cu seed film on the barrier film by the plasma sputtering; filling the trench or the hole by Cu plating; and removing a residual Cu thin film and a residual barrier film remaining on the wafer surface by CMP (Chemical Mechanical Polishing) (see, e.g., Japanese Patent Application Publication No. 2006-148075).

Meanwhile, as the semiconductor device is miniaturized, the width of the trench or the diameter of the hole becomes several tens of nm. In the case of forming the barrier film or the seed film in the recess such as the trench or the hole by the plasma sputtering, an overhang is formed at the opening of the trench or the hole. Even if the trench or the hole is filled by the Cu plating later, the trench or the hole is not completely filled and a void is formed.

In view of the above, there is proposed a method including: forming a base film made of Ta or TaN on a Low-k film made of a porous SiCOH-based material; forming a Ru film having good wettability with Cu on the base film by CVD (Chemical Vapor Deposition); and filling Cu (see, e.g., U.S. Patent Application Publication No. 2008/237860).

However, in the case of employing the above-described method which includes: forming the base film made of Ta or TaN; forming the Ru film on the base film; and filling Cu, a volume of a portion other than Cu in the recess such as the trench or the like is increased and the wiring resistance is increased by that amount. Further, the Low-k film made of a porous SiCOH-based material has low strength due to its multiple pores.

### SUMMARY OF THE INVENTION

In view of the above, the present invention provides a method for manufacturing a semiconductor device which is capable of realizing low resistance of Cu wiring by using a Low-k film having high strength.

In accordance with an aspect of the present invention, there is provided a semiconductor device manufacturing method including: performing nitrogen plasma processing on an interlayer insulating film including a fluorine containing carbon film having a recess formed in a surface thereof in a predetermined pattern; forming a Ru film directly on the fluorine containing carbon film subjected to the nitrogen plasma processing; and filling a Cu film in the recess to form a Cu wiring.

### BRIEF DESCRIPTION OF THE DRAWINGS

The objects and features of the present invention will become apparent from the following description of embodiments, given in conjunction with the accompanying drawings, in which:

FIG. 1 is a flowchart showing a semiconductor device manufacturing method in accordance with an embodiment of the present invention;

FIGS. 2A to 2F are process cross sectional views for explaining the semiconductor device manufacturing method in accordance with the embodiment of the present invention;

FIG. 3 is a top view showing an example of a film forming system for implementing the semiconductor device manufacturing method in accordance with the embodiment of the present invention;

FIG. 4 is a cross sectional view showing a Cu film forming device for use in forming a Cu film which is installed at the film forming system shown in FIG. 3; and

FIG. 5 is a cross sectional view showing a Ru film forming device for use in forming a Ru film which is installed at the film forming system shown in FIG. 3.

### DETAILED DESCRIPTION OF THE EMBODIMENTS

Hereinafter, an embodiment of the present invention will be described in detail with reference to the accompanying drawings.

<Embodiment of Semiconductor Device Manufacturing Method>

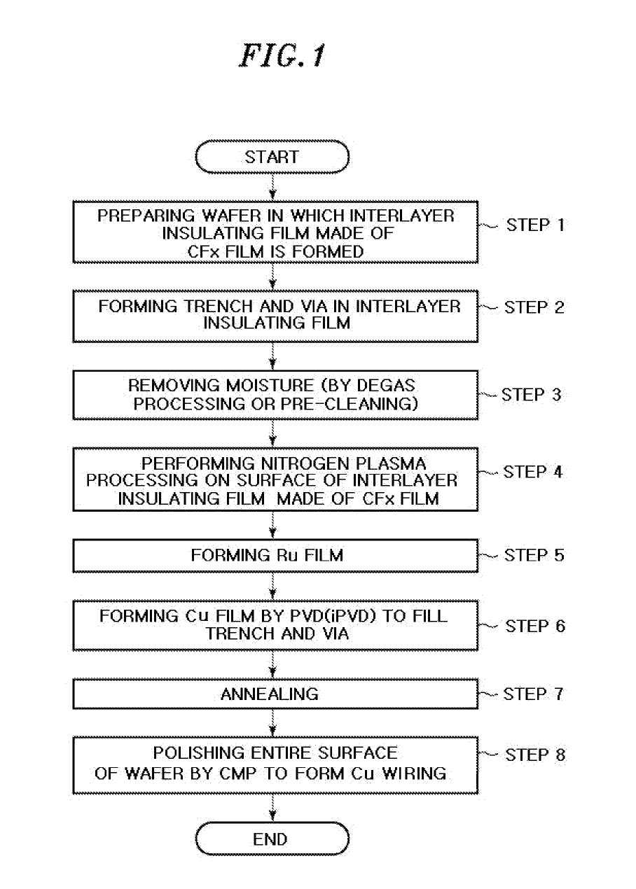

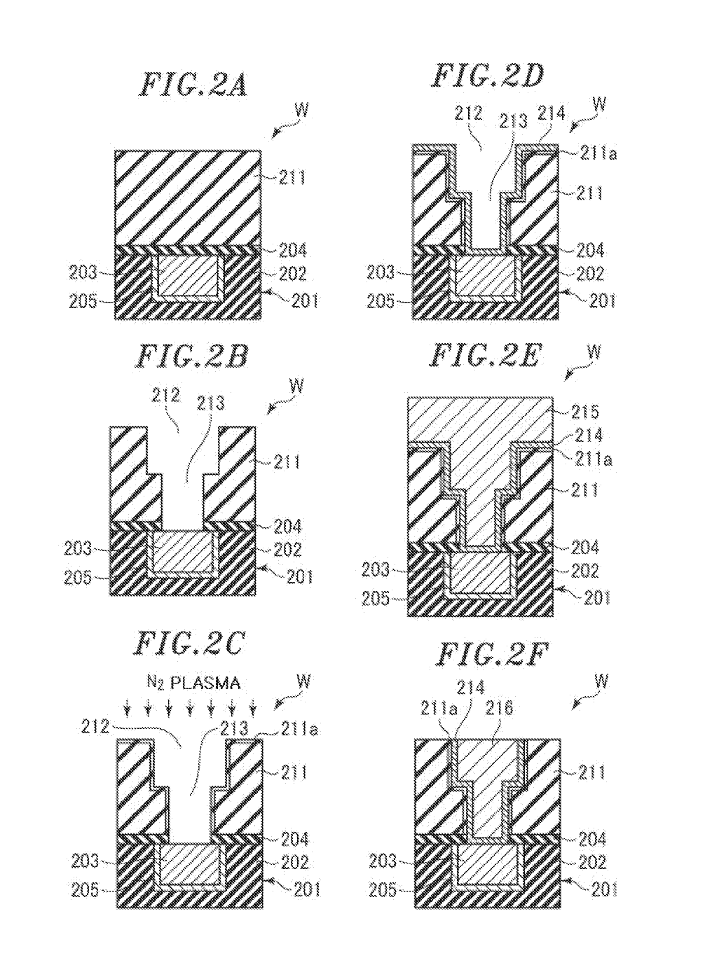

First, a semiconductor device manufacturing method in accordance with an embodiment of the present invention will be described with reference to a flowchart in FIG. 1 and process cross sectional views shown in FIGS. 2A to 2F. An example of forming Cu wiring using a dual damascene method in accordance with the present embodiment will be described.

In the present embodiment, first, there is prepared a semiconductor wafer W (hereinafter, simply referred to as “wafer”) in which an interlayer insulating film 211 made of a fluorine containing carbon film (fluorocarbon film (CFₓ film)) is formed on a lower wiring structure 201 in step 1 and FIG. 2A.

The lower wiring structure 201 has a structure in which a lower Cu wiring 203 is formed in a lower interlayer insulating film 202 and an etching stopper film 204 is formed thereon. A reference numeral 205 indicates a Ru film.

The CFₓ film constituting the interlayer insulating film 211 can be formed by a method disclosed in, e.g., PCT Publication No. WO2005/017991. In other words, the CFₓ film can be formed by forming a CFₓ film having hydrogen atoms of 3 atomic % or less on a substrate by using a plasma of a source gas and then heating the film at a temperature of 420° C. or less. The source gas includes an unsaturated carbon fluoride compound such as octafluorocyclopentene, octafluoro-2-pentine, hexafluoro-1,3-butadiene or the like and contains hydrogen atoms of 1×10⁻³ atomic % or less.

It has been newly found that the CFₓ film thus formed has a low dielectric constant of 2.2 or less and high strength due to its high density and also has a barrier property to Cu. The contents disclosed in PCT Publication No. WO2005/017991 are incorporated herein by reference as the disclosure of the present specification.

Next, a trench 212 and a via 213 for connection to the lower wiring are formed in a predetermined pattern by etching the interlayer insulating film 211, and a photoresist as an etching mask is removed by asking in step 2 and FIG. 2B.

Thereafter, if necessary, moisture on the surface of the interlayer insulating film 211 is removed by a degas process or a pre-clean process in step 3 (not shown in FIGS. 2A to 2F). Next, a modified layer 211a is formed on the surface of the interlayer insulating film 211 by performing nitrogen plasma (N₂ plasma) processing on the surface of the interlayer insulating film 211 in step 4 and FIG. 2C.

Then, a Ru film 214 is formed on the entire surface including the surfaces of the trench 212 and the via 213 by CVD in step 5 and FIG. 2D.

Next, a Cu film 215 is formed by PVD to fill the trench 212 and the via 213 in step 6 and FIG. 2E. As for the PVD, it is preferable to use ionized PVD (iPVD), as will be described later. In the case of forming the Cu film 215, it is preferable to form the Cu film 215 to be laminated beyond the top of the trench 212 in preparation for a planarization process to be performed later. Such a laminated portion may be formed by plating instead of consecutive formation of Cu film 215 by PVD. After the Cu film 215 is formed, an annealing process is performed if necessary in step 7 (not shown in FIGS. 2A to 2F). The Cu film 215 is stabilized by the annealing process.

Then, the entire top surface of the wafer W is polished by CMP (Chemical Mechanical Polishing), so that the laminated portion of the Cu film 215 and the Ru film 214 are removed and the top surface of the wafer W is planarized in step 8 and FIG. 2F. Accordingly, a Cu wiring 216 is formed in the trench and the via.

After the Cu wiring 216 is formed, a proper cap film such as a dielectric cap, a metal cap or the like is formed on the entire top surface of the wafer W which includes the surfaces of the Cu wiring 216 and the interlayer insulating film 211.

Hereinafter, main processes among the above series of processes will be described in detail.

In the step 4, the nitrogen plasma processing modifies a surface of the CFₓ film constituting the interlayer insulating film 211 into a hydrophilic surface.

In the present embodiment, since the CFₓ film having an excellent barrier property to Cu is used as the interlayer insulating film 211, the barrier property can be ensured without using the barrier film such as a Ta film, a TaN film or the like which has been conventionally used and, thus, the Ru film 214 is directly formed on the interlayer insulating film 211 made of the CFₓ film. However, when the surface of the fluorine containing carbon film (fluorocarbon film) is hydrophobic, the source gas for forming a Ru film is not easily adsorbed and, therefore, nucleation is insufficient. Therefore, it is difficult to form a continuous dense and smooth thin film. In view of realization of low resistance of wiring, the Ru film 214 needs to have a considerably thin thickness of 5 nm or less. However, it is difficult to uniformly form such a thin film on the surface having a hydrophobic property.

Therefore, the hydrophobic surface is modified to the hydrophilic surface by performing the nitrogen plasma processing on the surface of the interlayer insulating film 21 made of a fluorine containing carbon film (fluorocarbon film). As a result, the modified layer 211a is formed.

The method for modifying the hydrophobic surface to the hydrophilic surface may also be oxygen plasma processing or hydrogen plasma processing. However, the CFₓ film cannot be maintained because it is decomposed to a gaseous component and is consumed by etching by the following Reaction 1 in the case of performing the oxygen plasma processing and by the following Reaction 2 in the case of performing the hydrogen plasma processing.

CFₓ+O*→CO↑,CO₂↑,COF₂↑ (Reaction 1)

CFₓ+H*→HF↑,CHₓF_{y}↑,CH₄↑ (Reaction 2)

On the other hand, in the case of performing the nitrogen plasma processing, an extremely small amount of the CFₓ film is turned into a gas by the following Reaction 3 occurs. Further, CFₓN_{y} having a hydrophilic property is generated on the surface of the CFₓ film, so that the film surface is modified to a hydrophilic surface.

CFₓ+N*,N₂→CFₓN_{y}(s),CFₓN_{y}(g) (Reaction 3)

The nitrogen plasma processing may be carried out by generating a plasma of N₂ gas in the processing chamber where the wafer W having the interlayer insulating film 211 made of the CFₓ film is disposed. The plasma generation method is not particularly limited and may be an inductively coupled plasma generating method, a capacitively coupled plasma generating method or a microwave plasma generating method. Further, an N₂ plasma generated by a suitable method may be introduced into the processing chamber where the wafer W is disposed.

As for a gas for generating an N₂ plasma, only N₂ gas may be used, or a rare gas such as Ar gas or the like may be added to N₂ gas. Since it is only required to modify the surface of the CFₓ film to be hydrophilic, the nitrogen plasma processing may be performed only for a time period of about 0.1 sec to 10 sec.

A pressure in the processing chamber where the nitrogen plasma processing is to be carried out is preferably 1×10⁻⁷ Torr (1.33×10⁻⁵ Pa) or less. When impurities are all moisture, if the pressure is higher than 1×10⁻⁷ Torr, the surface of the CFₓ film is covered by the moisture during the above time period and, thus, the etching reaction may occur. Meanwhile, when the pressure is equal to or less than 1×10⁻⁷ Torr, a relatively long period of time is required until the surface of the CFₓ film is covered by the moisture and, thus, the etching on the surface of the CFₓ film hardly occurs during the above time period. Although the actual processing is performed after the pressure reaches about 1×10⁻⁷ Torr, the pressure in the processing chamber reaches several tens of mTorr due to the flow of N₂ gas or generation of the plasma.

In order to perform the processing at such a low pressure, it is preferable to use an iPVD apparatus for use in forming a Cu film which will be described later. The iPVD apparatus for use in a Cu film formation includes a high vacuum pump, so that a high vacuum state lower than or equal to 1×10⁻⁷ Torr can be easily obtained. A microwave plasma processing device is also preferably used because a high vacuum state can be easily obtained.

A test was conducted to examine the effect of the nitrogen plasma processing.

Here, a contact angle on the surface of the CFₓ film that has not been subjected to the nitrogen plasma processing was 106.6°. Next, the nitrogen plasma processing was performed on the CFₓ film by using the microwave plasma processing device under the following conditions.

Pressure: 18 mTorr (2.4 Pa)

Microwave power: 2.5 kW

RF bias (400 kHz) applied to the mounting table: 10 W

Substrate temperature: 380° C.

Processing gas: Ar gas (100 sccm), N₂ gas (900 sccm)

Processing time: 4 sec

After the processing, the contact angle on the surface of the CFₓ film was 47.1°. This shows that the hydrophobic surface of the CFₓ film was modified to the hydrophilic surface.

The same effect was obtained when the nitrogen plasma processing was performed by using an iPVD apparatus same as that for use in formation of a Cu film under the following conditions.

Pressure: 65 mTorr (8.7 Pa)

Power supplied to an IPC coil: 5.25 kW

RF bias (13.56 MHz) applied to the mounting table: 200 W

Substrate temperature: 10° C.

Processing gas: Ar gas (478 sccm), N₂ gas (23 sccm)

Processing time: 4 sec

Next, the formation of the Ru film 214 will be described.

Since Ru has high wettability to Cu, forming the Ru film as an underlayer of Cu ensures good mobility of Cu in forming a Cu film by using iPVD, and it becomes possible to suppress to form an overhang which blocks an opening of the trench or the hole. Therefore, Cu can be reliably filled even in a fine trench or hole without forming a void therein.

Further, the Ru film 214 serves as a barrier film for Cu. In the present embodiment, the Ru film 214 is directly formed on the interlayer insulating film 211 made of the CFₓ film without using the conventional barrier film such as a Ta film, a TaN film or the like. Since the CFₓ film has a barrier property to Cu and the Ru film 214 has a barrier function as described above, the barrier property to Cu can be sufficiently ensured.

The Ru film 214 preferably has a thin thickness ranging from about 1 nm to 5 nm in order to realize a low resistance of the wiring by increasing the volume of Cu to be filled.

The Ru film 214 is preferably formed by thermal CVD while using Ru₃(CO)₁₂ (ruthenium carbonyl) as a film forming source material. Accordingly, a thin Ru film having high purity can be formed with a high step coverage. The film forming conditions are as follows:

a pressure in the processing chamber ranging from 1.3 Pa to 66.5 Pa; and

a film forming temperature (wafer temperature) ranging from 150° C. to 250° C.

The Ru film 214 may be formed by the thermal CVD using another film forming source material other than Ru₃(CO)₁₂, such as a ruthenium pentadienyl compound, e.g., (cyclopentadienyl)(2,4-dimethylpentadienyl)ruthenium, bis(cyclopentadienyl)(2,4-methylpentadienyl)ruthenium, (2,4-dimethylpentadienyl)(ethylcyclopentadienyl)ruthenium, or bis(2,4-methylpentaenyl)(ethylcyclopentadienyl)ruthenium.

Next, the formation of the Cu film 215 will be described.

The Cu film 215 can be formed by PVD. However, it is preferable to form the Cu film 215 by iPVD, e.g., plasma sputtering, as described above. Further, the laminated portion may be formed by plating instead of consecutive formation by PVD.

In the conventional film formation using the PVD, the overhang that blocks the opening of the trench or the hole is easily formed due to agglomeration of Cu. However, when the iPVD is applied, the film forming action by Cu ions and the etching action by ions (Ar ions) of the plasma generation gas are controlled while adjusting the bias power applied to the wafer and, thus, Cu is moved to thereby suppress the formation of the overhang. As a consequence, good fillability can be obtained even in a trench or a hole having a narrow opening.

At this time, in order to ensure mobility of Cu and obtain good fillability, it is preferable to perform a high-temperature process (in a temperature ranging from 65° C. to 350° C.) in which Cu is migrated. By performing the film formation using the iPVD at such a high temperature, Cu crystal grains can grow and grain boundary scattering is reduced, thereby reducing the resistance of the Cu wiring. Further, as described above, by providing the Ru film 214 having high wettability to Cu under the Cu film 215, Cu moves without agglomeration on the Ru film. Accordingly, the formation of overhang can be suppressed even in a fine recess, and Cu can be reliably filled therein without forming a void.

When an overhang hardly occurs due to a large opening width of a trench or a hole, a film can be rapidly formed by a relatively low temperature process (in a temperature ranging from −50° C. to 0° C.) in which Cu is not migrated.

Further, a pressure in the processing chamber during the formation of the Cu film (processing pressure) preferably ranges from about 1 mTorr to 100 mTorr (about 0.133 Pa to 13.3 Pa) and more preferably ranges from about 35 mTorr to 90 mTorr (about 4.66 Pa to 12.0 Pa).

As described above, the semiconductor device manufacturing method in accordance with the present embodiment can solve the problem in that the porous SiCOH-based material has low strength by using the CFₓ film that is a dense Low-k film as the interlayer insulating film 211. Since CFₓ film has a high barrier property, the barrier property to Cu can be sufficiently ensured only by the Ru film 214 without the conventionally used barrier film. Accordingly, the volume of Cu in the trench 212 or the via 213 can be increased by an amount that the barrier film is omitted and, thus, the resistance of the Cu wiring 216 can be reduced. Further, the surface of the CFₓ film has a hydrophobic property and, thus, it is difficult to directly form a Ru film thereon. However, the modified layer 211a having a hydrophilic property is formed at the surface of the CFₓ film forming the interlayer insulating film 211 by performing the nitrogen plasma processing on the CFₓ film. As a result, the Ru film can be directly formed on the surface of the CFₓ film.

Among the above series of processes, the step 5 of forming the Ru film 214 and the step 6 of forming the Cu film 215 are preferably executed consecutively in vacuum without being exposed to the atmosphere. However, the wafer may be exposed to the atmosphere between the steps 5 and 6.

<Film Forming System Suitable for Implementing an Embodiment of the Present Invention>

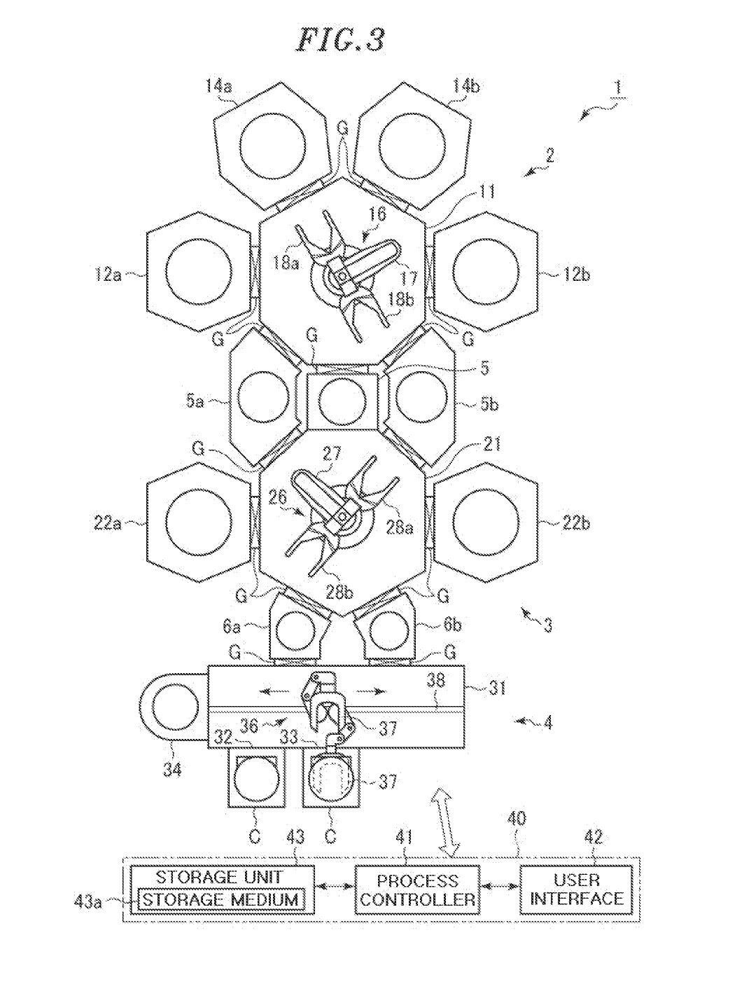

Hereinafter, a film forming system suitable for implementing the semiconductor device manufacturing method in accordance with the embodiment of the present invention will be described. FIG. 3 is a plan view showing an example of a multi-chamber type film forming system 1 suitable for implementing the semiconductor device manufacturing method in accordance with the embodiment of the present invention.

The film forming system 1 includes a first processing apparatus 2 for performing nitrogen plasma processing and forming a Ru film; a second processing apparatus 3 for forming a Cu film; and a loading/unloading unit 4. The film forming system 1 is provided to perform processes from nitrogen plasma processing up to the formation of the Cu film on the wafer W which has the CFₓ film as the interlayer insulating film and is formed with a trench and a via in a predetermined pattern.

The first processing apparatus 2 has a first vacuum transfer chamber 11, and two nitrogen plasma processing devices 12a and 12b and two Ru film forming devices 14a and 14b which are connected to walls of the first vacuum transfer chamber 11. The nitrogen plasma processing device 12a and the Ru film forming device 14a are disposed in line symmetry with the nitrogen plasma processing device 12b and the Ru film forming device 14b.

Degas chambers 5a and 5b each for performing a degas process on the wafer W are connected to other walls of the first vacuum transfer chamber 11. Further, a transfer chamber 5 through which the wafer W is transferred between the first vacuum transfer chamber 11 and a second vacuum transfer chamber 21 to be described later is connected to a wall of the first vacuum transfer chamber 11 which is disposed between the degas chambers 5a and 5b.

The nitrogen plasma processing devices 12a and 12b, the Ru film forming devices 14a and 14b, the degas chambers 5a and 5b, and the transfer chamber 5 are connected to the respective sides of the first vacuum transfer chamber 11 via gate valves G. They communicate with the first vacuum transfer chamber 11 by opening the corresponding gate valves G and are isolated from the first vacuum transfer chamber 11 by closing the corresponding gate valves G.

The inside of the first vacuum transfer chamber 11 is maintained at a predetermined vacuum atmosphere. Provided in the first vacuum transfer chamber 11 is a first transfer mechanism 16 for loading and unloading the wafer W. The first transfer mechanism 16 is disposed substantially at the center of the first vacuum transfer chamber 11 and has a rotatable and extensible/contractible portion 17. The rotatable and extensible/contractible portion 17 has, at its leading end, two support arms 18a and 18b for supporting the wafer W. The first transfer mechanism 16 loads and unloads the wafer W into and from the nitrogen plasma processing devices 12a and 12b, the Ru film forming devices 14a and 14b, the degas chambers 5a and 5b, and the transfer chamber 5.

The second processing apparatus 3 includes: a second vacuum transfer chamber 21 and two Cu film forming devices 22a and 22b connected to two opposite walls of the second vacuum transfer chamber 21. The Cu film forming devices 22a and 22b may be used to perform processes of filling the recess and forming the laminated portion collectively. Or, the Cu film forming devices 22a and 22b may be used only for the filling the recess, and the laminated portion may be formed by plating.

The degas chambers 5a and 5b are connected to walls of the second vacuum transfer chamber 21 which face the first processing apparatus 2, and the transfer chamber 5 is connected to a wall of the second vacuum transfer chamber 21 between the degas chambers 5a and 5b. In other words, the transfer chamber 5 and the degas chambers 5a and 5b are provided between the first vacuum transfer chamber 11 and the second vacuum transfer chamber 21, and the degas chambers 5a and 5b are disposed at both sides of the transfer chamber 5. Moreover, load-lock chambers 6a and 6b that allow atmospheric transfer and vacuum transfer are connected to two walls of the second vacuum transfer chamber 21 which face the loading/unloading unit 4.

The Cu film forming devices 22a and 22b, the degas chambers 5a and 5b, and the load-lock chambers 6a and 6b are connected to the respective sides of the second vacuum transfer chamber 21 via gate valves G. They communicate with the second vacuum transfer chamber 21 by opening the corresponding valves G and are isolated from the second vacuum transfer chamber 21 by closing the corresponding gate valves G. The transfer chamber 5 is connected to the second transfer chamber 21 without providing a gate valve therebetween.

The inside of the second vacuum transfer chamber 21 is maintained at a predetermined vacuum atmosphere. Provided in the second vacuum transfer chamber 21 is a second transfer mechanism 26 for loading and unloading the wafer W into and from the Cu film forming devices 22a and 22b, the degas chambers 5a and 5b, the load-lock chambers 6a and 6b and the transfer chamber 5. The second transfer mechanism 26 is disposed substantially at the center of the second vacuum transfer chamber 21 and has a rotatable and extensible/contractible portion 27. The rotatable and extensible/contractible portion 27 has, at its leading end, two support arms 28a and 28b for supporting the wafer W. The two support arms 28a and 28b are attached to the rotatable and extensible/contractible portion 27 to be oriented in the opposite directions.

The loading/unloading unit 4 is provided at an opposite side to the second processing apparatus 3 with the load-lock chamber 6 therebetween. The loading/unloading unit 4 has an atmospheric transfer chamber 31 connected to the load-lock chambers 6a and 6b. Gate valves G are provided at a wall between the load-lock chambers 6a and 6b and the atmospheric transfer chamber 31. Provided at a wall of the atmospheric transfer chamber 31 opposite to the wall connected to the load-lock chambers 6a and 6b are two connection ports 32 and 33 each for connecting carriers C accommodating therein wafers W as target substrates.

Further, an alignment chamber 34 is provided at a side surface of the atmospheric transfer chamber 31, and alignment of the wafer W is executed therein. Provided in the atmospheric transfer chamber 31 is an atmospheric transfer mechanism 36 for loading and unloading the wafer W into and from the carrier C. The atmospheric transfer mechanism 36 has two multi-joint arms and can move on a rail along the arrangement direction of the carriers C. Therefore, the atmospheric transfer mechanism 36 transfers wafers W while mounting the wafer W on each of hands 37 provided at leading ends of the respective arms.

The film forming system 1 includes a controller 40 configured to control the respective components of the film forming system 1. The controller 40 includes a process controller 41 having a microprocessor (computer) for controlling the respective components, a user interface 42 and a storage unit 43. The user interface 42 includes a keyboard through which an operator inputs a command to manage the film forming system 1, a display for visually displaying the operational states of the film forming system 1 and the like. The storage unit 43 stores therein control programs to be used in realizing various processes performed in the film forming system 1 under the control of the process controller 41, and programs, i.e., processing recipes, to be used in controlling the respective components of the processing apparatuses to carry out processes under processing conditions and various data. The user interface and the storage unit 43 are connected to the process controller 41.

The processing recipes are stored in a storage medium 43a in the storage unit 43. The storage medium 43a may be a hard disk or a portable medium such as a CD-ROM, a DVD, a flash memory or the like. Alternatively, the recipes may be suitably transmitted from other devices through, e.g., a dedicated transmission line.

If necessary, a specific recipe is read out from the storage unit 43 under an instruction from the user interface and is executed by the process controller 41. Accordingly, a desired process is performed in the film forming system 1 under the control of the process controller 41.

In the film forming system 1, the wafer W having trenches and holes formed in a predetermined pattern is unloaded from the carrier C and is loaded into the load-lock chamber 6a or 6b by the atmospheric transfer mechanism 36. After the pressure in the load-lock chamber 6a or 6b is decreased to a vacuum level substantially equivalent to that in the second vacuum transfer chamber 21, the wafer W is unloaded from the load-lock chamber 6a or 6b to be loaded into the degas chamber 5a or 5b through the second vacuum transfer chamber 21 by the second transfer mechanism 26. Thus, the wafer W is subjected to the degas process.

Thereafter, the wafer W is unloaded from the degas chamber 5a or 5b and is loaded into the nitrogen plasma processing device 12a or 12b through the first vacuum transfer chamber 11 by the first transfer mechanism 16. Thus, the nitrogen plasma processing as described above is performed to modify the surface of the CFₓ film as the interlayer insulating film 211 to a hydrophilic surface. After the nitrogen plasma processing is completed, the wafer W is unloaded from the nitrogen plasma processing device 12a or 12b to be loaded into the Ru film forming device 14a or 14b by the first transfer mechanism 16. Thus, the Ru film as described above is formed.

After the Ru film is formed, the wafer W is unloaded from the Ru film forming device 14a or 14b and transferred into the transfer chamber 5 by the first transfer mechanism 16. Next, the wafer W is unloaded from the transfer chamber 5 to be loaded into the Cu film forming device 22a or 22b through the second vacuum transfer chamber 21 by the second transfer mechanism 26. Thus, the Cu film is formed and the trench and the via are filled with Cu. At this time, the laminated portion may also be formed. Or, the Cu film forming device 22a or 22b may perform only the filling the trench and the via, and the laminated portion may be formed by plating.

After the Cu film is formed, the wafer W is transferred to the load-lock chamber 6a or 6b. After the pressure in the load-lock chamber is returned to the atmospheric pressure, the wafer W having the Cu film is unloaded and is returned to the carrier C by the atmospheric transfer mechanism 36. Such processes are repeated for the number of wafers W in the carrier C.

In accordance with the film forming system 1, nitrogen plasma processing, forming the Ru film, filling the trench and via, and forming the laminated portion of Cu can be performed in the vacuum atmosphere without being exposed to the atmosphere. Accordingly, oxidation at the surface of each film formed after each process can be prevented, and a high-performance Cu wiring can be obtained.

After the processing in the film forming system 1 is completed, the carrier C is transferred to the CMP processing unit and subjected to CMP processing.

<Cu Film Forming Device>

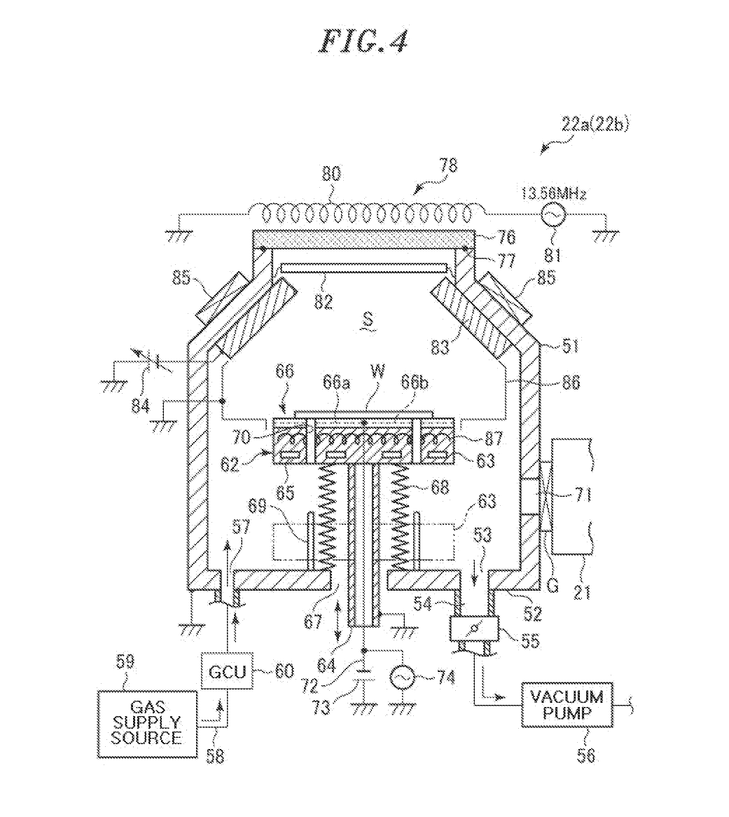

Hereinafter, an example of the Cu film forming device 22a (22b) for use in forming a Cu film will be described. FIG. 4 is a cross sectional view showing an example of the Cu film forming device.

Here, an ICP (Inductively Coupled Plasma) type plasma sputtering apparatus, i.e., an iPVD apparatus will be described as an example of the Cu film forming device.

As shown in FIG. 4, the Cu film forming device 22a (22b) includes a cylindrical processing chamber 51 made of metal. The processing chamber 51 is grounded, and a gas exhaust port 53 is provided at a bottom portion 52 thereof. A gas exhaust passage 54 is connected to the gas exhaust port 53. The gas exhaust passage 54 is provided with a throttle valve 55 and a vacuum pump 56 for a pressure control to thereby evacuate the inside of the processing chamber 51 to vacuum. Further, a gas inlet 57 for introducing a predetermined gas into the processing chamber 51 is provided at the bottom portion 52 of the processing chamber 51. The gas inlet 57 is connected to, through a gas supply line 58, a gas supply source 59 for supplying a rare gas serving as a plasma excitation gas, e.g., Ar gas, or another required gas, e.g., N₂ gas or the like. The gas supply line 58 is provided with a gas control unit (GCU) 60 having a flow rate controller, a valve and the like.

Provided in the processing chamber 51 is a mounting mechanism 62 for mounting thereon a wafer W. The mounting mechanism 62 has a circular plate-shaped conductive mounting table 63 and a hollow cylindrical support column 64 for supporting the mounting table 63. The mounting table 63 is grounded via the support column 64. The mounting table 63 has therein a cooling jacket 65 and a resistance heater 87 provided above the cooling jacket 65. The mounting table 63 is provided with a thermocouple (not shown). A temperature of the wafer can be controlled by the cooling jacket 65 and the resistance heater 87 based on the temperature detected by the thermocouple.

Provided on the top surface of the mounting table 63 is a thin circular plate-shaped electrostatic chuck 66 including a dielectric member 66a and an electrode 66b embedded in the dielectric member 66a. Accordingly, the wafer W can be attracted and held by an electrostatic force. The lower portion of the support column 64 extends downward through an insertion hole 67 formed at the center of the bottom portion 52 of the processing chamber 51. The support column 64 is vertically movable by an elevation unit (not shown), so that the entire mounting mechanism 62 is vertically moved.

An extensible/contractible metal bellows 68 is provided to surround the support column 64. The metal bellows 68 has a top end hermetically attached to the bottom surface of the mounting table 63 and a bottom end hermetically attached to the top surface of the bottom portion 52 of the processing chamber 51. Accordingly, the mounting mechanism 62 can be vertically moved while maintaining the airtightness in the processing chamber 51.

Further, a plurality of, e.g., three (only two are shown) support pins 69 is uprightly mounted on the bottom portion 52 toward the up side, and pin insertion holes 70 are formed in the mounting table 63 so as to correspond to the support pins 69. Therefore, when the mounting table 63 is lowered, the top end portions of the support pins 69 pass through the pin insertion holes 70 to receive the wafer W, so that the wafer W is transferred to/from a transfer arm (not shown) which comes from outside. A loading/unloading port 71 through which the transfer arm is moved in and out is provided at a lower sidewall of the processing chamber 51, and an openable/closeable gate valve G is provided at the loading/unloading port 71. The second vacuum transfer chamber 21 is provided on the opposite side of the gate valve G to the processing chamber 51.

A chuck power supply 73 is connected to the electrode 66b of the electrostatic chuck 66 through a power supply line 72. By applying a DC voltage from the chuck power supply 73 to the electrode 66b, the wafer W is attracted and held by an electrostatic force. Further, an RF bias power supply 74 is connected to the power supply line 72, so that an RF bias power is applied to the electrode 66b of the electrostatic chuck 66 through the power supply line 72 to apply a bias power to the wafer W. The frequency of the RF power is preferably in a range from 400 kHz to 60 MHz, e.g., about 13.56 MHz.

An RF transmitting plate 76 made of a dielectric material is hermitically provided at the ceiling portion of the processing chamber 51 through a seal member 77. Further, a plasma generating source 78, for generating a plasma from a rare gas as a plasma excitation gas, e.g., Ar gas, in a processing space S of the processing chamber 51, is provided above the transmitting plate 76.

The plasma generating source 78 has an induction coil 80 disposed to correspond to the transmitting plate 76. An RF power supply 81 having a high frequency of, e.g., 13.56 MHz, for plasma generation is connected to the induction coil 80. Accordingly, an RF power is supplied to the induction coil 80 and introduced into the processing space S through the transmitting plate 76, and an induced electric field is formed in the processing space S.

Moreover, a baffle plate 82 made of metal is provided directly under the transmitting plate 76 to diffuse the introduced RF power. A hollow truncated cone-shaped target 83 made of Cu is disposed below the baffle plate 82 to surround the upper region of the processing space S. A variable-voltage DC power supply 84 is connected to the target 83 to apply a DC power for attracting Ar ions. Alternatively, an AC power supply may be used instead of the DC power supply.

Further, a magnet 85 is provided at an outer circumferential side of the target 83 to apply a magnetic field to the target 83. The target 83 is sputtered by Ar ions in the plasma, so that metal atoms or metal atom groups of Cu are emitted from the target 83 and they are mostly ionized while passing through the plasma.

In addition, a cylindrical protection cover member 86 is provided below the target 83 to surround the processing space S. The protection cover member 86 is grounded, and an inner end thereof is disposed to surround the outer peripheral side of the mounting table 63a.

In the Cu film forming device 22a (22b) configured as described above, the wafer W is loaded into the processing chamber 51 and is mounted on the mounting table 63. Then, the wafer W is electrostatically attracted and held on the electrostatic chuck 66. At this time, the temperature of the mounting table 63 is controlled by the cooling jacket 65 or the resistance heater 87 based on the temperature detected by the thermocouple (not shown).

In that state, the following operations are carried out under the control of the control unit 40.

First, the processing chamber 51 is set to a high vacuum state of 1×10⁻⁷ Torr or less by operating the vacuum pump 56. Then, Ar gas is supplied into the processing chamber 51 at a predetermined flow rate by controlling the gas control unit 60 while the processing chamber 51 is maintained at a predetermined vacuum level by controlling the throttle valve 55. Next, a DC power is applied to the target 83 from the variable DC power supply 84, and an RF power (plasma power) is supplied to the induction coil 80 from the RF power supply 81 of the plasma generating source 78. Further, a predetermined RF bias power is supplied from the RF bias power supply 74 to the electrode 66b of the electrostatic chuck 66.

Hence, in the processing chamber 51, an Ar plasma is generated by the RF power supplied to the induction coil 80. Ar ions in the Ar plasma are attracted toward the target 83 by the DC voltage applied to the target 83 to collide with the target 83. The target 83 is sputtered to emit Cu particles. At this time, the amount of particles emitted from the target 83 is optimally controlled by the DC voltage applied to the target 83.

The Cu particles from the sputtered target 83 are mostly ionized while passing through the plasma. The ionized particles and electrically neutral atoms are mixed and are scattered downward. The ionization rate at this time is controlled by the RF power supplied from the RF power supply 81.

When the ions are introduced into an ion sheath region formed above the wafer W with a thickness of about a few mm by the RF bias power applied from the RF bias power supply 74 to the electrode 66b of the electrostatic chuck 66, the ions are attracted with strong directivity toward the wafer W. As a consequence, the Cu film is formed on the wafer W.

At this time, the wafer temperature is set to be maintained at a high level (in a range from 65° C. to 350° C.), and the bias power applied from the RF bias power supply 74 to the electrode 66b of the electrostatic chuck 66 is controlled. With such control, the formation of the Cu film and the etching using Ar are controlled to facilitate the mobility of Cu. As a result, Cu can be filled with good fillability even in a trench or a hole having a small opening.

In view of ensuring good fillability, the pressure in the processing chamber 51 (processing pressure) is preferably set in a range from 1 mTorr to 100 mTorr (0.133 Pa to 13.3 Pa) and more preferably set in a range from 35 mTorr to 90 mTorr (from 4.66 Pa to 12.0 Pa). The DC power supplied to the target is preferably set in a range from 4 kW to 12 kW and more preferably set in a range from 6 kW to 10 kW.

When the opening of the trench or the hole is relatively large, the film formation can be carried out at a high forming rate by decreasing the pressure in the processing chamber 51 and setting a wafer temperature at a low level (in a range from −50° C. to 0° C.). Further, when the opening width is large, the conventional PVD such as conventional sputtering, ion plating or the like can be used without being limited to the iPVD.

<Nitrogen Plasma Processing Device>

Hereinafter, the nitrogen plasma processing device 12a (12b) will be described.

As described above, the nitrogen plasma processing is preferably performed by an apparatus capable of setting the pressure in the processing chamber to 1×10⁻⁷ Torr or less. An apparatus having the same configuration as that of the Cu film forming device 22a (22b) may be used for performing the nitrogen plasma processing. In other words, an apparatus having the configuration of the Cu film forming device 22a (22b) from which the target 83 is omitted may be used. In this case, a plasma of N₂ gas is formed by introducing a gas containing N₂ gas into the processing chamber 51 through the gas inlet 57 and generating an induced electric field in the processing space S by supplying an RF power to the induction coil 80 while setting the inside of the processing chamber 51 to a high vacuum atmosphere of 1×10⁻⁷ Torr or less.

Accordingly, the nitrogen plasma processing can be performed on the CFₓ film as the interlayer insulating film of the wafer W at a low pressure. The configuration of the apparatus is not limited thereto as long as the inside of the processing chamber can be maintained at a high vacuum atmosphere of 1×10⁻⁷ Torr or less, and another apparatus such as a capacitively coupled plasma processing device, a microwave plasma processing device or the like may also be used.

<Ru Film Forming Device>

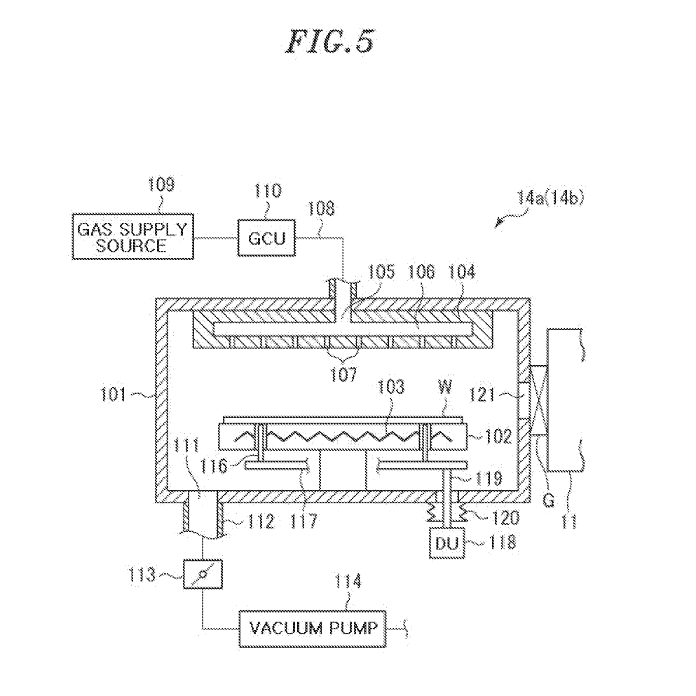

Hereinafter, the Ru film forming device 14a (14b) for use in forming the Ru film will be described. The Ru film may be preferably formed by thermal CVD. FIG. 5 is a cross sectional view showing an example of the Ru film forming device for forming the Ru film by the thermal CVD.

As shown in FIG. 5, the Ru film forming device 14a (14b) includes a cylindrical processing chamber 101 made of, e.g., aluminum or the like. The processing chamber 101 has therein a mounting table 102 made of ceramic, e.g., AlN or the like, for mounting thereon the wafer W. The mounting table 102 has therein a heater 103. The heater 103 generates a heat by a power supplied from a heater power supply (not shown).

A shower head 104 is provided at the ceiling wall of the processing chamber 101 to be opposite to the mounting table 102. Through the shower head 104, a purge gas or a processing gas for forming the Ru film is introduced into the processing chamber 101 in the form of shower. The shower head 104 has a gas inlet 105 at a top portion thereof and a gas diffusion space 106 therein. A plurality of gas injection openings 107 is formed in the bottom of the shower head 104. A gas supply line 108 is connected to the gas inlet 105, and a gas supply source 109 is connected to the gas supply line 108 to supply the purge gas or the processing gas for forming the Ru film. Further, a gas control unit (GCU) 110 including a gas flow rate controller, a valve and the like is disposed on the gas supply line 108. As described above, Ru₃(CO)₁₂ (ruthenium carbonyl) may be preferably used as a Ru film forming gas. The Ru film can be formed by thermally decomposing Ru₃(CO)_{12.}

A gas exhaust port 111 is provided at the bottom portion of the processing chamber 101, and a gas exhaust passage 112 is connected to the gas exhaust port 111. The gas exhaust passage 112 is provided with a throttle valve 113 and a vacuum pump 114 for a pressure control, so that the processing chamber 101 can be exhausted to vacuum.

The mounting table 102 is configured such that three wafer support pins 116 (only two pins are shown) for transferring a wafer can protrude from and retreat into the surface of the mounting table 102. The wafer support pins 116 are fixed on a support plate 117. The wafer support pins 116 are vertically moved together with the support plate 117 by vertically moving a rod 119 by a driving unit (DU) 118 such as an air cylinder or the like. Reference numeral 120 denotes a bellows. A wafer loading/unloading port 121 is formed at a sidewall of the processing chamber 101, so that a wafer W can be loaded into and unloaded from the first vacuum transfer chamber 11 in a state where a gate valve G is opened.

In the Ru film forming device 14a (14b), the gate valve G is opened and the wafer W is mounted on the mounting table 102. Then, the gate valve G is closed, and the processing chamber 101 is evacuated by the vacuum pump 114 so that the pressure in the processing chamber 101 is controlled to be maintained at a predetermined level. In a state where the wafer W is heated to a predetermined temperature through the mounting table 102 by the heater 103, a processing gas such as ruthenium carbonyl (Ru₃(CO)₁₂) or the like is introduced into the processing chamber 101 from the gas supply source 109 through the gas supply line 108 and the shower head 104. Accordingly, the processing gas reacts on the surface of the wafer W, and the Ru film can be formed on the wafer W.

The Ru film may be formed by using another film forming material other than ruthenium carbonyl, e.g., the aforementioned ruthenium pentadienyl compounds, together with a decomposition gas such as O₂ gas.

<Apparatus Used for Other Processes>

Although the processes from the nitrogen plasma processing up to the formation of the laminated portion in the above embodiment can be carried out by the above-described film forming system 1, the post processes such as the annealing and the CMP may be performed on the wafer W unloaded from the film forming system 1 by using an annealing apparatus and a CMP apparatus. These apparatuses may have general configurations. When these apparatuses and the film forming system 1 constitute the Cu wiring forming system and are controlled by a common controller having the same function as that of the controller 40, the method described in the above embodiment can be executed by a single recipe.

<Other Applications>

While the embodiment of the present invention has been described, the present invention may be variously modified without being limited to the above embodiment. For example, the film forming system is not limited to the type shown in FIG. 3 and may employ a type in which all the film forming devices are connected to a single transfer unit. Instead of the multi-chamber type system shown in FIG. 3, there may be employed a system in which some of the nitrogen plasma processing, the formation of a Ru film and the formation of a Cu film are performed in the same film forming system and the others are performed in separate apparatuses while being exposed to the atmosphere between the processes. Alternatively, the respective processes may be performed in separate apparatuses while being exposed to the atmosphere between the processes.

In the above embodiment, the example in which the method in accordance with the present invention is applied to the wafer having a trench and a via (hole) is described. However, the present invention may be applied to the case in which a wafer has a trench or a hole only. Further, the method in accordance with the present invention may be applied to the single damascene as well as the double damascene. Furthermore, the method may be applied to filling in devices of various structures such as a 3D mounting structure or the like. Further, although a semiconductor wafer is described as an example of a target substrate in the above embodiment, the semiconductor wafer may include a compound semiconductor such as GaAs, SiC, GaN or the like as well as a silicon. Further, the present invention may be applied to a ceramic substrate, a glass substrate for use in a FPD (flat panel display) such as a liquid crystal display or the like, and the like without being limited to a semiconductor wafer.

In accordance with the embodiment of the present invention, the problem that the porous SiCOH-based material has low strength can be solved by using the fluorine containing carbon film for the Low-k film used as the interlayer insulating film. Further, since the fluorine containing carbon film has high barrier property, the barrier property to Cu can be ensured by the Ru film without using the barrier film such as a Ta film, a TaN film or the like which has been conventionally used. Therefore, the volume of Cu in the recess can be increased by an amount corresponding to the absence of the barrier film, and the resistance of the Cu wiring can be further reduced.

Moreover, a hydrophobic property of the surface of the fluorine containing carbon film makes adsorption of a source gas for forming the Ru film thereon difficult and, thus, it is difficult to directly form the Ru film on the surface of the fluorine containing carbon film. However, the surface of the fluorine containing carbon film can have a hydrophilic property by performing nitrogen plasma processing thereon. As a result, the Ru film can be directly formed on the surface of the fluorine containing carbon film.

While the invention has been shown and described with respect to the embodiments, it will be understood by those skilled in the art that various changes and modifications may be made without departing from the scope of the invention as defined in the following claims.

What is claimed is:

1. A semiconductor device manufacturing method comprising:
performing nitrogen plasma processing on an interlayer insulating film including a fluorine containing carbon film having a recess formed in a surface thereof in a predetermined pattern;
forming a Ru film directly on the fluorine containing carbon film subjected to the nitrogen plasma processing; and
filling a Cu film in the recess to form a Cu wiring.

2. The semiconductor device manufacturing method of claim 1, wherein the nitrogen plasma processing is performed in a processing chamber while maintaining a pressure in the processing chamber at 1×10⁻⁷ Torr or less.

3. The semiconductor device manufacturing method of claim 1, wherein the filling the Cu film is performed by PVD.

4. The semiconductor device manufacturing method of claim 1, wherein the Cu film is filled by an apparatus in which a plasma is generated by using a plasma generation gas in a processing chamber accommodating a substrate therein, Cu particles are sputtered from a Cu target in the processing chamber, the Cu particles are ionized in the plasma, and Cu ions are attracted onto the substrate by applying a bias power to the substrate.

5. The semiconductor device manufacturing method of claim 1, wherein the Ru film is formed by CVD.
